(19) United States
(12) Patent Application Publication
(10) Pub. No.: US 2005/0181915 A1
(43) Pub. Date: Aug. 18, 2005

(54) Constant resistance exercising apparatus and system

(76) Inventors: Dietrich Hoecht, Clayton, GA (US); Michael P. Ross, San Diego, CA (US); Fred Bohm, Carlsbad, CA (US)

Correspondence Address: MYERS & KAPLAN, INTELLECTUAL PROPERTY LAW, L.L.C., 1899 POWERS FERRY ROAD, SUITE 310, ATLANTA, GA, 30339, US

(21) Appl. No.: 11/044,578

(22) Filed: Jan. 27, 2005

Related U.S. Application Data
(60) Provisional application No. 60/539,147, filed on Jan. 27, 2004.

(51) Int. Cl. G01R 33/06; A63B 21/02; A63B 21/045

(52) U.S. Cl. 482/127; 482/121; 482/128

(57) ABSTRACT

A constant resistance exercising apparatus and system comprising a series of resistance units, each comprising a storage drum, output drum, and a constant torque spring wound about each drum. Each resistance unit may be selectively actuated through a lever and clutch assembly that simply slides a gear arrangement in and out of contact with a respective output drum. Accordingly, through the effortless toggling of a lever, a user may select or deselect multiple resistance units to provide a desired quantitative and measurable level of constant resistive force. Exercise tools, including handgrips, leg cuffs, bars, and/or harnesses, may be connected to a cable extending from the resistance units, and thus, function as the interface between the exercising apparatus and the user.

### CROSS-REFERENCE AND PRIORITY CLAIM TO RELATED APPLICATIONS

To the fullest extent permitted by law, the present nonprovisional patent application claims priority to and the full benefit of provisional patent application entitled “Mechanism to Transmit Constant Resistance in Selectable Increments”, filed on Jan. 27, 2004, having assigned Ser. No. 60/539,147 wherein said application is incorporated herein by reference.

### TECHNICAL FIELD

The present invention relates generally to exercise machines, and more specifically to a constant resistance exercising apparatus and system designed to provide incremental adjustment or selectable variance of total constant force resistive output during resistance training.

### BACKGROUND OF THE INVENTION

Resistance training commonly refers to the controlled and repetitive displacement of a load or weight within a specific range of motion, and against a resistive force. Such resistance training is traditionally utilized to improve sports performance, rehabilitate injuries, prevent injuries, and/or enhance long-term health, and often encompasses the application of conventional weights, pneumatic or hydraulic resistance machines, resistance bands, and/or ergometer devices.

Disadvantageously, however, many of the afore-referenced resistance training devices and machines are generally ineffective resistance training tools, and/or fail to provide a measurable constant quantitative force on the muscle, the latter of which is imperative for optimal muscle maintenance and reduction of exercise-induced injuries.

Accordingly, in an attempt to provide constant force resistive output for effective resistance training, some resistance exercise designs incorporate constant torque springs as the resistive force element. Typically, such resistance exercise designs comprise a series of constant torque flat coil springs, wherein each such spring is partially wound upon a rotationally-fixed storage drum according to the natural curvature of the spring, and further partially wound upon a separate, and rotationally-fixed, output drum in a direction opposite to the natural curvature of the spring. A cable, mechanically-coupled to the output drum, is pulled so as to rotate the storage and output drums in opposite directions and, thereby, pull or unwind a length of spring from the storage drum, and sequentially wind the length of spring around the output drum. In such a configuration, energy is stored in the length of reverse-coiled spring disposed about the output drum. Release of the cable consequently results in unwinding of the spring from the output drum and sequential rewinding of the spring around the storage drum; thus, releasing the stored energy and providing a constant torque.

An example of a constant force resistive exercise unit (CFREU) utilizing such constant torque spring technology may be seen with reference to U.S. Pat. No. 6,685,602 B2 to Colosky, Jr. et al. (Colosky), wherein the CFREU utilizes modular resistive packs comprising the constant torque spring arrangement as described hereinabove. However, although effective in providing a constant resistive force for proper resistance training, the Colosky device exhibits several structural and functional complexities and limitations that render use of the Colosky device largely impractical and onerous.

In particular, Colosky teaches that the total constant force resistive output may be adjusted by mechanically interconnecting a plurality of modular resistive packs. Specifically, as disclosed in Colosky, fixedly secured to one side of the output drum of each resistive pack is a hollow selection mechanism which encloses an output shaft. The user actuates the selection mechanism of each resistive pack by attaching an attachment flange via attachment holes and bolts (or other suitable mechanical fasteners) to the side of the output drum through threaded holes. The output shaft housing portion of the selection mechanism also houses the output shaft, wherein the output shaft runs through a selection mechanism shaft hole. The selection mechanism output shaft housing has one plunger hole designed to accommodate a perpendicular selection plunger to engage the output drum with the output shaft, wherein the plunger hole must be directly aligned with the output shaft selection mechanism attachment hole in the output shaft.

To rotate the output shaft for direct alignment of its plunger hole with the selection mechanism plunger hole, Colosky teaches that the user must first deselect all resistive packs by withdrawing their plungers from plunger holes so the output shaft can rotate freely. Next, the user must rotate a selector knob, which is fixedly attached to the output shaft, until the selection mechanism plunger hole aligns with the output shaft plunger hole in a particular resistive pack. To engage one resistive pack to provide resistive forces during exercise, the selection plunger must be manually pushed completely through the selection mechanism housing, through the plunger hole, and into the output shaft plunger hole, to operationally engage the output drum of that resistive pack to the output shaft. Colosky still further discloses spring-loaded plungers that may be utilized in lieu of the pin-like plungers described hereinabove, wherein each spring-loaded plunger must be lifted and rotated to free the plunger from the plunger hole, and similarly depressed and rotated to lock the plunger within a plunger hole.

As is illustrated in the foregoing description, Colosky's plunger-and-hole arrangement, and associated multi-step method for operationally coupling multiple resistive packs, imposes significant burden and time-loss on its user. Indeed, the user must go through no less than four (4) steps before obtaining the desired total resistive force: first, the user must deselect all resistive packs by withdrawing their plungers from plunger holes so the output shaft can rotate freely; second, rotate a selector knob to align all selection mechanism plunger hole aligns with the output shaft plunger hole; third, manually engage a plunger through an aligned hole of a particular resistive pack; and fourth, similarly sequentially manually engage each resistive pack until a total desired resistive force is achieved. Additional steps and layers of complexity are experienced with application of Colosky's spring-loaded plungers. Ultimately, such a structure and methodology of resistive pack coupling can prove an onerous task, especially for the less mechanically inclined, physically-challenged or arthritically-hindered user.

Therefore, it is readily apparent that there is a need for a constant resistance exercising apparatus and system utilizing constant torque spring technology, and designed to provide expeditious and effortless selectivity or variance of total constant force resistive output during resistance training.

### BRIEF SUMMARY OF THE INVENTION

Briefly described, in a preferred embodiment, the present invention overcomes the above-mentioned disadvantage, and meets the recognized need for such a device by providing a constant resistance exercising apparatus and system comprising a series of resistance units, each comprising a storage drum, output drum, and a constant torque spring wound about each drum. Each resistance unit may be selectively actuated through a lever and clutch assembly that simply slides a gear arrangement in and out of contact with a respective output drum. Accordingly, through the effortless toggling of a lever, a user may select or deselect multiple resistance units to provide a desired quantitative and measurable level of constant resistive force. Exercise tools, including handgrips, leg cuffs, bars, and/or harnesses, may be connected to a cable extending from the resistance units, and thus, function as the interface between the exercising apparatus and the user.

According to its major aspects and broadly stated, the present invention in its preferred form is a constant resistance exercising apparatus and system comprising a series of resistance units, each comprising a storage drum, output drum, a constant torque spring wound about each drum, a bevel gear arrangement, a lever-actuated pinion assembly, and a cable and cable drum assembly.

More specifically, the present invention is a constant resistance exercising apparatus and system comprising a plurality of resistance units, each comprising a constant torque flat coil spring partially wound upon a rotationally-fixed storage drum according to the natural curvature of the spring, and further partially wound upon an output drum in a direction opposite to the natural curvature of the spring, wherein each output drum is preferably rotationally-fixed upon an output shaft.

Preferably disposed on each output shaft of each output drum is a concentrically and axially-affixed bevel gear. A common or primary shaft, rotationally-fixed proximate and perpendicular to each output shaft of each resistance unit, preferably comprises a plurality of pinions concentrically and axially-disposed thereabout, wherein each pinion is preferably disposed proximate to each bevel gear of each output shaft. Accordingly, through the simple toggling of a lever, a selected pinion of the primary shaft may be cooperatively engaged to, and similarly disengaged from, a respective bevel gear of a respective output shaft for a particular resistance unit.

Preferably, a cable drum, comprising a cable wound thereabout, is affixed to a terminal end of the primary shaft. Accordingly, upon “activation” of a desired number of resistance units, the primary shaft may be rotationally actuated via manually pulling the cable from the cable drum. Rotation of the primary shaft preferably rotates the storage and output drums in opposite directions and, thereby, pulls or unwinds the spring from the storage drum, and sequentially winds the spring around the output drum. The energy stored in the reverse-coiled spring disposed about the output drum, is preferably released upon release of the cable, which results in unwinding of the spring from the output drum and sequential rewinding of the spring around the storage drum; thus, yielding a constant torque.

The cable may be drawn through a simple pulley system, wherein the distal end of the cable may be coupled to a variety of accessories, such as handgrips, leg cuffs, bars, harnesses, and the like, to provide a variety of exercises.

The present invention further contemplates the sandwiching or “lamination” of multiple constant torque springs within a resistance unit, since breakage of the spring within a single-spring resistance unit may present a safety hazard for the user. That is, in a single-spring resistance unit, if the user pulls the cable, and the spring breaks within the resistance unit, then the user may abruptly experience zero resistance and, thus, lose balance. However, by “laminating” or sandwiching together more than one spring, breakage of one of the springs within the resistance unit will not cause such momentary zero resistance, as the remaining spring(s) within the “sandwich” function as back-up springs; thus, avoiding potential user injury.

Lamination of a plurality of springs further contributes to the overall reduction of component parts; thereby, reducing the number of total resistance units, and enabling the design of a relatively compact resistance unit, and exercise apparatus, generally, without compromising the total resistance offered thereby. As such, a plurality of springs may be combined or laminated to provide varying resistances amongst each resistance unit, or in any other selected arrangement.

Additionally, the present invention may be utilized as the primary resistive force in replacement of weight stacks commonly found in larger multi-choice resistance exercising machines, such as, for exemplary purposes only, the weight stacks and related weight accessories utilized in the exercise apparatus of U.S. Pat. No. 6,443,877 B1 to Hoecht et al. In such a configuration and design, the operational and spatial requirements of the exercise apparatus embodied in the foregoing referenced patent may be significantly reduced and, thereby, provide a relatively compact and portable exercise unit.

Accordingly, a feature and advantage of the present invention is its ability to provide a constant force resistive output.

Another feature and advantage of the present invention is its ability to provide expeditious and effortless selectivity or variance of total constant force resistive output during resistance training.

Still another feature and advantage of the present invention is its bevel gear and lever-actuated pinion arrangement for expeditious and effortless engagement and disengagement of a respective resistance unit.

Yet another feature and advantage of the present invention is its ability to be independently utilized as an exercise unit.

Still yet another feature and advantage of the present invention is its ability to be utilized as the primary resistive force in replacement of weight stacks commonly found in larger multi-choice resistance exercising machines.

A further feature and advantage of the present invention is its sandwiching or “lamination” of multiple constant torque springs, which provides a significant safety feature.

Another and further feature and advantage of the present invention is its low system weight compared to gravity weight machines. Accordingly, the low-weight of the present invention, individually, or combined with multi-choice resistance exercising machines, reduces overall packaging costs, manufacturing costs, and shipping costs.

These and other features and advantages of the invention will become more apparent to one skilled in the art from the following description and claims when read in light of the accompanying drawings.

### BRIEF DESCRIPTION OF THE DRAWINGS

The present invention will be better understood by reading the Detailed Description of the Preferred and Alternate Embodiments with reference to the accompanying drawing figures, in which like reference numerals denote similar structure and refer to like elements throughout, and in which:

FIG. 1 is a cross-sectional view of a constant resistance exercising apparatus and system according to a preferred embodiment of the present invention; and,

FIG. 2 is a cross-sectional view of a constant resistance exercising apparatus and system according to a preferred embodiment of the present invention.

### DETAILED DESCRIPTION OF THE PREFERRED AND ALTERNATIVE EMBODIMENTS

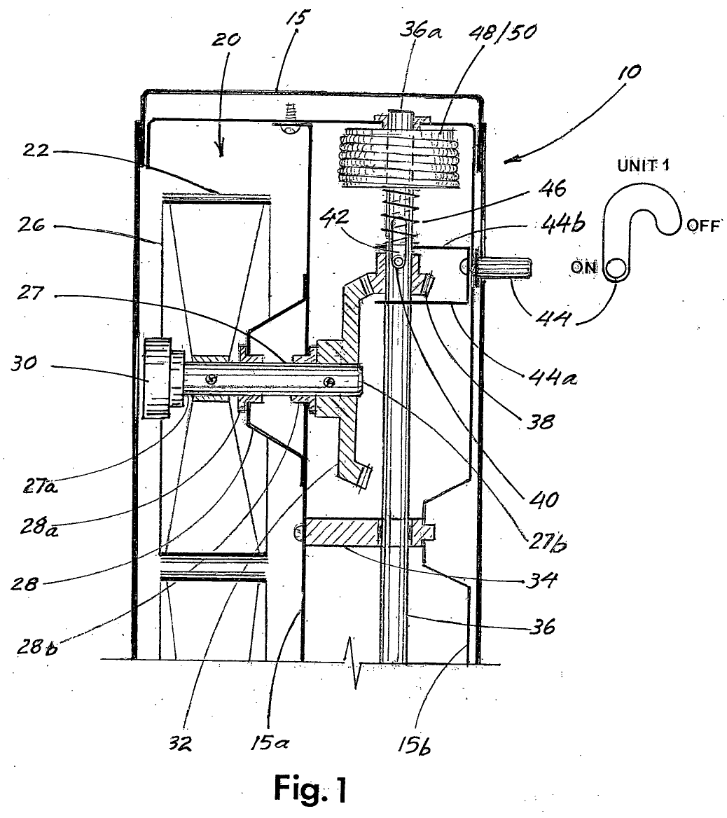

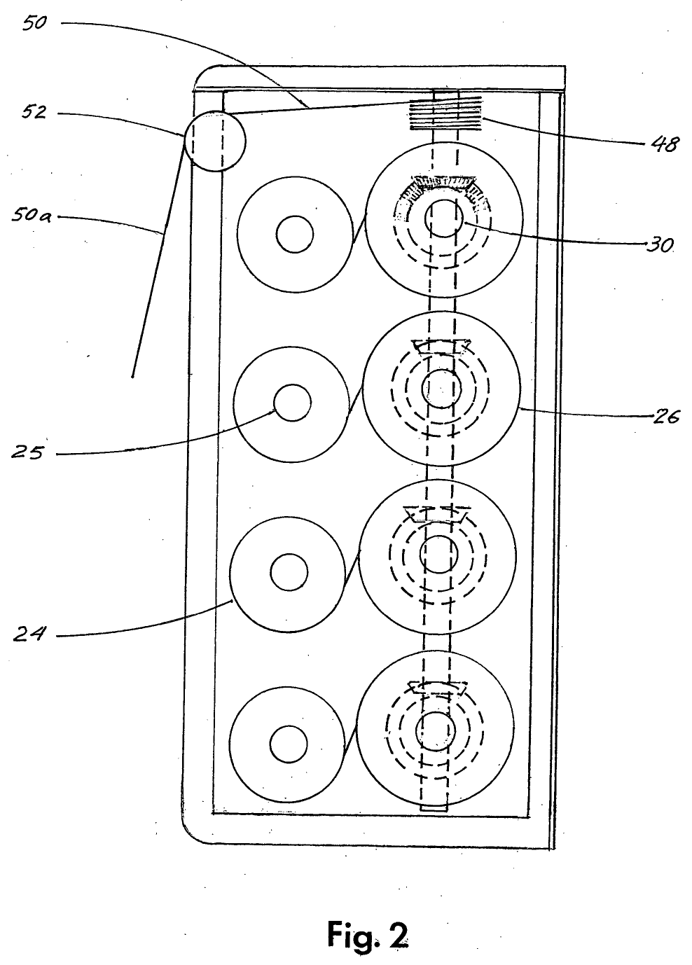

In describing the preferred and alternate embodiments of the present invention, as illustrated in FIGS. 1-2, specific terminology is employed for the sake of clarity. The invention, however, is not intended to be limited to the specific terminology so selected, and it is to be understood that each specific element includes all technical equivalents that operate in a similar manner to accomplish similar functions.

Referring now to FIGS. 1-2, the present invention in its preferred embodiment is a constant resistance exercising apparatus and system 10 comprising housing 15 within which are disposed resistance units 20. Each resistance unit 20 preferably comprises constant torque flat coil spring 22 partially wound upon storage drum 24 according to the natural curvature of spring 22, and further partially wound upon output drum 26 in a direction opposite to the natural curvature of spring 22. As is best illustrated in FIG. 2, each output drum 26 is preferably disposed proximate to a respective storage drum 24, between which extends spring 22.

Preferably disposed within housing 15 are support brackets 15a, 15b. Each storage drum 24 of each resistance unit 20 is preferably rotationally mounted to support bracket 15a via a respective storage drum shaft 25. Similarly, each output drum 26 of each resistance unit 20 is preferably mounted to a respective output shaft 27, wherein each output shaft 27 extends through and is rotationally engaged within a respective mounting hub 28 via bearing assemblies 28a, 28b. Each mounting hub 28 is preferably secured to support bracket 15a via bolts, screws, rivets, or the like. Additionally, and as more fully described below, each output shaft 27 preferably extends through support bracket 15a.

Each output drum 26 is preferably retained on output shaft 27 via a respective knob 30, wherein each knob 30 is preferably threadably received by proximal end 27a of a respective output shaft 27, and wherein each knob 30 further facilitates the expeditious installation and/or removal of a respective output drum therefrom, as more fully described below. Each distal end 27b of each output shaft 27 preferably extends through support bracket 15a, wherein each distal end 27b of each output shaft 27 preferably comprises a concentrically and axially-affixed bevel gear 32, for purpose more fully described below.

Preferably extending from support bracket 15b are stand-offs 34, wherein a common or primary shaft 36 preferably extends through and is rotationally-fixed within each such stand-off 34. Primary shaft 36 is preferably disposed proximate and perpendicular to output shafts 27 of each resistance unit 20. Further, primary shaft 36 comprises pinions 38 concentrically and axially-disposed thereabout, wherein pinions 38 are preferably equivalent in number to the total sum of resistance units 20 within housing 15. Accordingly, each pinion 38 is preferably disposed proximate to a respective bevel gear 32 of a respective output shaft 27. Each pinion 38 is further preferably coupled to primary shaft 36 via a respective pin 40, wherein each pin 40 is preferably slidably engaged and retained within a respective slot 42 formed on primary shaft 36; thereby, enabling each pinion 38 to simply slide in and out of contact with a respective bevel gear 32 of a particular output shaft 27, as more fully described below.

Each pinion 38 is preferably cradled by arms 44a, 44b of a respective lever 44, wherein each lever 44 extends through support bracket 15b, and through housing 15, for toggling or positional manipulation by a user. That is, toggling a lever 44 from an “off” to an “on” position of a selected resistance unit 20, preferably results in a respective pinion 38 cooperatively engaging a respective bevel gear 32 of a respective output shaft 27; thereby, actuating that particular resistance unit 20. Additionally, preferably disposed on primary shaft 36, and adjacent to each arm 44a of each lever 44, is a respective compression spring 46, wherein each compression spring 46 ensures proper and secured teeth engagement between pinion 38 and bevel gear 32 of an actuated resistance unit 20, by acting on, or applying a force against, arm 44a and, thus, communicating pinion 38. Advantageously then, through the simple toggling of a selected lever 44, any selected pinion 38 of primary shaft 36 may be cooperatively engaged to, and similarly disengaged from, any respective bevel gear 32 of any selected resistance unit 20; thereby, enabling expeditious and effortless adjustment or selective variance of total constant force resistive output.

Preferably, cable drum 48, comprising cable 50 wound thereabout, is affixed to terminal end 36a of primary shaft 36. Accordingly, upon actuation or “activation” of a desired number of resistance units 20, primary shaft 36 may be rotationally actuated via manually pulling distal end 50a of cable 50 from cable drum 48, wherein cable 50 is generally preferably guided and retained within pulley 52 disposed within housing 15, and wherein distal end 50a of cable 50 thereafter preferably exists housing 15 through an appropriate slot or aperture thereof.

Rotation of primary shaft 36 preferably rotates storage drum 24 and output drum 26 in opposite directions and, thereby, pulls or unwinds spring 22 from storage drum 24, and sequentially winds spring 22 around output drum 26. The energy stored in the reverse-coiled spring 22 disposed about output drum 26, is preferably released upon release of cable 50, which results in unwinding of spring 22 from output drum 26 and sequential rewinding of spring 22 around storage drum 24; thus, yielding a constant torque.

Distal end 50a of cable 50 may be coupled to a variety of accessories, such as handgrips, leg cuffs, bars, harnesses, and the like, to facilitate withdrawal of cable 50 from cable drum 48, and accordingly provide a variety of exercises.

As addressed hereinabove, should a user desire to remove an output drum 26 to replace or repair same, and/or access other components of each resistance unit 20, a selected knob 30 is preferably unthreaded or unscrewed from proximal end 27a of a respective output shaft 27, and output drum 26 removed therefrom. It should be recognized that storage drums 24 may also be removably secured to respective storage drum shafts 25 via similarly threadably engaged knobs.

The present invention further contemplates the sandwiching or “lamination” of multiple constant torque springs 22 within a resistance unit 20, since breakage of spring 22 within a single-spring resistance unit 20 may present a safety hazard for the user. That is, in a single-spring resistance unit 20, if the user pulls cable 50, and spring 22 breaks within resistance unit 20, then the user may abruptly experience zero resistance and, thus, lose balance. However, by “laminating” or sandwiching together more than one spring 22, breakage of one of springs 22 within resistance unit 20 will not cause such momentary zero resistance, as the remaining spring(s) 22 within the “sandwich” function as back-up springs; thus, avoiding potential user injury.

Lamination of a plurality of springs 22 further contributes to the overall reduction of component parts; thereby, reducing the number of total resistance units 20, and enabling the design of a relatively compact resistance unit 20, and exercise apparatus 10, generally, without compromising the total resistance offered thereby. As such, a plurality of springs 22 may be combined or laminated to provide varying resistances amongst each resistance unit 20, or in any other selected arrangement.

In is contemplated that the present invention may be utilized as the primary resistive force in replacement of weight stacks commonly found in larger multi-choice resistance exercising machines, such as, for exemplary purposes only, the weight stacks and related weight accessories utilized in the exercise apparatus of U.S. Pat. No. 6,443,877 B1 to Hoecht et al. In such a configuration and design, the operational and spatial requirements of the exercise apparatus embodied in the foregoing referenced patent may be significantly reduced and, thereby, provide a relatively compact and portable exercise unit.

It is further contemplated that the present invention could incorporate multiple cable-and-cable drum assemblies, each coupled to a series of stacked resistance units 20; thereby, enabling the contemporaneous performance of more than one resistance training exercise.

It is still further contemplated that a variety of gear ratios may be applied to bevel gear 32 and pinion 38; thereby, tailoring total resistive force output and torque of each resistance unit 20.

It is still yet further contemplated that should resistance units 20 be placed within a larger exercise apparatus, or utilized individually, lever 44 may be ergonomically positioned above-waist level to facilitate adjustment of total resistance. Such a feature is especially advantageous for the elderly, physically-challenged and/or arthritically-hindered, wherein conventional weight-based equipment would otherwise require such users to bend over or kneel down onto the floor to adjust total weight or resistance.

Having thus described exemplary embodiments of the present invention, it should be noted by those skilled in the art that the within disclosures are exemplary only, and that various other alternatives, adaptations, and modifications may be made within the scope of the present invention. Accordingly, the present invention is not limited to the specific embodiments illustrated herein, but is limited only by the following claims.

1. A constant resistance exercising apparatus, comprising:
a resistance unit, said resistance unit comprising a storage drum, an output drum, and a constant torque spring at least partially wound around each said drum; and,
a gear arrangement, wherein said gear arrangement enables actuation of said resistance unit.

2. The apparatus of claim 1, wherein said constant torque spring is a constant torque flat coil spring comprising a natural curvature.

3. The apparatus of claim 2, wherein said constant torque spring is partially wound upon said storage drum according to said natural curvature of said spring, and further partially wound upon said output drum in a direction opposite to said natural curvature of said spring.

4. The apparatus of claim 1, wherein said storage drum is rotationally mounted upon a storage drum shaft, and wherein said output drum is rotationally mounted upon an output shaft, said output shaft comprising a proximal end and a distal end.

5. The apparatus of claim 4, wherein said proximal end of said output shaft comprises a knob removably securable thereto, wherein said knob retains said output drum upon said output shaft, and further enables removal of said output drum from said output shaft.

6. The apparatus of claim 4, wherein said distal end of said output shaft comprises a first portion of said gear arrangement, said first portion comprising a concentrically and axially-affixed bevel gear.

7. The apparatus of claim 6, further comprising a rotationally-fixed primary shaft disposed proximate to said output shaft.

8. The apparatus of claim 7, wherein said primary shaft comprises a second portion of said gear arrangement, wherein said second portion comprises a pinion concentrically and axially-disposed about said primary shaft.

9. The apparatus of claim 8, wherein said pinion is slidably engaged over said primary shaft, and wherein said pinion comprises a lever coupled thereto for slidably moving said pinion in and out of cooperative engagement with said bevel gear.

10. The apparatus of claim 9, further comprising a compression spring disposed proximate to said pinion, wherein said compression springs provides a spring-force to ensure proper and secured teeth engagement between said pinion and said bevel gear.

11. The apparatus of claim 10, further comprising a cable drum and a cable wound thereabout, wherein said cable drum is affixed to said primary shaft, and wherein said primary shaft may be rotationally actuated via manually pulling said cable.

12. The apparatus of claim 11, wherein rotation of said primary shaft rotates said storage drum and said output drum in opposite directions and, thereby, pulls or unwinds said spring from said storage drum, and sequentially winds said spring around said output drum, and wherein release of said cable results in unwinding of said spring from said output drum and sequential rewinding of said spring around said storage drum and, thus, releasing energy and yielding a constant torque.

13. The apparatus of claim 1, wherein said constant torque spring comprises a plurality of constant torque flat coil springs sandwiched or laminated to each other.

14. An apparatus for selectively actuating at least one of a plurality of resistance units for adjusting the total constant force resistive output therefrom, wherein each resistance unit comprises a storage drum, an output drum, and a constant torque spring at least partially wound around each drum, said apparatus comprising:
a first gear member coupled to the output drum of the resistance unit;
a second gear member coupled to a rotationally-fixed shaft, wherein said second gear member is slidably engaged to said shaft, and wherein slidable movement of said second gear member over said shaft cooperatively engages said second gear member with said first gear member.

15. The apparatus of claim 14, wherein said first gear member is a bevel gear concentrically and axially-affixed about the output drum of the resistance unit.

16. The apparatus of claim 14, wherein said second gear member is a pinion concentrically and axially-disposed about said shaft.

17. The apparatus of claim 16, wherein said pinion comprises a lever coupled thereto for slidably moving said pinion in and out of cooperative engagement with said first gear member.

18. The apparatus of claim 14, further comprising a compression spring disposed proximate to said second gear member, wherein said compression springs provides a spring-force to ensure proper and secured teeth engagement between said second gear member and said first gear member.

19. A multi-choice exercise apparatus comprising:
a first and a second module separated from each other by a frame, each said module comprising a resistance unit, each said resistance unit comprising a storage drum, an output drum, and a constant torque spring at least partially wound around each said drum;
each said module further comprising an azimuth locking plate affixed to a side of said resistance unit, and a hinge pin disposed rearward of said azimuth locking plate, said hinge pin defining a vertical axis of rotation of said module thereabout, said hinge pin interconnecting said module to said frame;
each said module being individually pivotable about said vertical axis of rotation; and,
a cable carried by a forward portion of each said resistance unit, said cable being pivotable with a respective said module about said vertical axis of rotation;
whereby said apparatus enables a user thereof to exercise separate limbs at the same time, but in optionally differing planes and with optionally differing resistance, all within a near hemispherical space.

20. The multi-choice exercise apparatus of claim 19, wherein said resistance unit further comprises a first gear member coupled to said output drum, and a second gear member coupled to a rotationally-fixed shaft, wherein said second gear member is slidably engaged to said shaft, and wherein slidable movement of said second gear member over said shaft cooperatively engages said second gear member with said first gear member.

21. The multi-choice exercise apparatus of claim 20, wherein said second gear member comprises a lever coupled thereto for slidably moving said second gear member in and out of cooperative engagement with said first gear member.

22. The multi-choice exercise apparatus of claim 21, further comprising a compression spring disposed proximate to said second gear member, wherein said compression springs provides a spring-force to ensure proper and secured teeth engagement between said second gear member and said first gear member.
